(19) United States
(12) Patent Application Publication
(10) Pub. No.: US 2021/0032741 A1
(43) Pub. Date: Feb. 4, 2021

(54) Fe-Pt-OXIDE-BN-BASED SINTERED COMPACT FOR SPUTTERING TARGET

(71) Applicant: TANAKA KIKINZOKU KOGYO K.K., Tokyo (JP)

(72) Inventors: Masahiro Nishiura, Ibaraki (JP); Takamichi Yamamoto, Ibaraki (JP); Kenta Kurose, Ibaraki (JP); Hironori Kobayashi, Ibaraki (JP); Takanobu Miyashita, Ibaraki (JP)

(21) Appl. No.: 16/982,375

(22) PCT Filed: Mar. 18, 2019
(86) PCT No.: PCT/JP2019/011073

§ 371 Date: Sep. 18, 2020

(30) Foreign Application Priority Data
Mar. 20, 2018 (JP) 2018-052851

(51) Int. Cl. C23C 14/34; C22C 1/05; C22C 32/00

(52) U.S. Cl. CPC C23C 14/3414; B22F 3/10; C22C 32/0005; C22C 1/05

(57) ABSTRACT

Provided is an Fe—Pt-oxide-BN-based sintered compact for a high-density sputtering target that can suppress generation of particles during sputtering.

The Fe—Pt-oxide-BN-based sintered compact for a sputtering target has a mass ratio of N to B (N/B) in a range of 1.30±0.1.

### TECHNICAL FIELD

The present invention relates to an Fe—Pt-oxide-BN-based sintered compact for a sputtering target and a production method therefor.

### BACKGROUND ART

Fe—Pt alloys can have, through heat treatment at a high temperature (600° C. or higher, for example), a fct (ordered face-centered tetragonal) structure with high magnetocrystalline anisotropy and thus draw attention as magnetic recording media. Such Fe—Pt-based magnetic recording media are formed by depositing Fe and Pt by using Fe—Pt-based sputtering targets. Since particles generated during sputtering lower the product yield, suppressed generation of particles is needed.

Various Fe—Pt-based sputtering targets composed of Fe—Pt alloy magnetic phase and nonmagnetic phase existing between the magnetic phase have been proposed. In these sputtering targets, oxides, such as SiO₂, BN (boron nitride), and C, for example, are often used as nonmagnetic phases.

For example, Patent Literature (PTL) 1 (JP5567227B) discloses an Fe—Pt-based magnetic material sintered compact comprising hexagonal BN and SiO₂ as nonmagnetic materials, where Si and O are present in a region where B or N is present at a cut surface of the sintered compact. Specifically, it is disclosed that 0.5 μm or more and 10 μm or less of Fe powder, Pt powder, BN powder, and SiO₂ powder were placed in a ball mill and stirred/mixed at 300 rpm for 2 hours; the resulting mixed powder was sintered at 950° C. and 30 MPa; and subsequently, the resulting sintered compact was subjected to hot isostatic pressing at 950° C. and 150 MPa, thereby manufacturing an Fe—Pt—SiO₂—BN sintered compact with a relative density of 98.3% (Example 2).

Moreover, PTL 2 (JP5913620B) discloses a sputtering target of BN-containing Fe—Pt-based sintered compact, where a ratio of an X-ray diffraction peak intensity of hexagonal BN (002) plane in a plane horizontal to a sputtering surface relative to an X-ray diffraction peak intensity of hexagonal BN (002) plane in a cross-section perpendicular to the sputtering surface is 2 or more. Specifically, it is disclosed that Fe—Pt alloy powder and SiO₂ powder were placed in a ball mill, pulverized through stirring/mixing at 300 rpm for 2 hours to form tabular or flake alloy powder, then added with BN powder (flakes), and mixed by using a 100 μm sieve; the resulting mixed powder was sintered at 1,100° C. and 30 MPa; and subsequently, the resulting sintered compact was subjected to hot isostatic pressing at 1,100° C. and 150 MPa, thereby manufacturing an Fe—Pt-SiO₂—BN sintered compact having, in the cross-sectional direction perpendicular to the sputtering surface, a layered structure where BN is oriented (Example 2).

### CITATION LIST

### Patent Literature

PTL 1: Japanese Patent No. 5567227

PTL 2: Japanese Patent No. 5913620

### SUMMARY OF INVENTION

### Technical Problem

The inventions disclosed in PTL 1 and 2 are directed to an Fe—Pt—SiO₂—BN sintered compact having a density enhanced by hot isostatic pressing after sintering at a high temperature of 950° C. or 1,100° C. Hot isostatic pressing after sintering increases the number of manufacturing steps, requires equipment for hot isostatic pressing, and is thus complicated.

An object of the present invention is to provide, without performing hot isostatic pressing, an Fe—Pt-oxide-BN-based sintered compact for a high-density sputtering target that can suppress generation of particles during sputtering.

### Solution to Problem

It is generally known that the density of a sintered compact increases as the sintering temperature is elevated. However, the present inventors observed a phenomenon that when a sintering temperature for producing an Fe—Pt-oxide-BN sintered compact is set to the conventionally common sintering temperature of 950° C. or higher and 1,300° C. or lower, the relative density is rather lowered while generating a large number of particles during sputtering.

The present inventors intensively studied the cause why the relative density is rather lowered when a sintering temperature for producing an Fe—Pt-oxide-BN sintered compact is set to a high temperature. As a result, it was found that the N content of an Fe—Pt-oxide-BN-based sintered compact prepared through high-temperature sintering is less than the theoretical value. The reduced N content was attributed to decomposition of BN and the resulting generation of nitrogen gas or nitrogen oxide gas due to prolonged contact between BN and an oxide as well as high-temperature sintering. In view of this, the present inventors found optimal conditions, from mixing conditions and sintering conditions for BN and an oxide, for suppressing decomposition of BN and generation of nitrogen gas or nitrogen oxide gas, thereby completing the present invention.

According to the present invention, an Fe—Pt-oxide-BN-based sintered compact for a sputtering target in the following embodiments is provided.

[1] An Fe—Pt-oxide-BN-based sintered compact for a sputtering target, where a mass ratio of N to B (N/B) is in a range of 1.30±0.1.

[2] The Fe—Pt-oxide-BN-based sintered compact for a sputtering target according to

[1] above, where a relative density measured by the Archimedes method is 92.0% or more.

[3] The Fe—Pt-oxide-BN-based sintered compact for a sputtering target according to

[1] or [2] above, comprising 33 mol % or more and 60 mol % or less of Pt and 5 mol % or more and 40 mol % or less of BN and an oxide in total, with the balance being Fe and incidental impurities.

[4] The Fe—Pt-oxide-BN-based sintered compact for a sputtering target according to

[1] or [2] above, comprising 33 mol % or more and 60 mol % or less of Pt, 5 mol % or more and 40 mol % or less of BN and an oxide in total, and 1 mol % or more and 15 mol % or less of one or more selected from Co, Zn, Ge, Rh, Ru, and Pd, with the balance being Fe and incidental impurities.

[5] The Fe—Pt-oxide-BN-based sintered compact for a sputtering target according to [1] or [2] above, comprising 33 mol % or more and 60 mol % or less of Pt, 5 mol % or more and 40 mol % or less of BN and an oxide in total, and 1 mol % or more and 15 mol % or less of C, with the balance being Fe and incidental impurities.

[6] The Fe—Pt-oxide-BN-based sintered compact for a sputtering target according to any one of [1] to [5] above, where the oxide is selected from Si oxide, Ti oxide, and Ta oxide.

[7] A method of producing the Fe—Pt-oxide-BN-based sintered compact for a sputtering target according to any one of [1] to [6] above, comprising: mixing a metal powder, an oxide powder, and a BN powder; and sintering at a temperature of 850° C. or lower.

[8] A method of producing the Fe—Pt-oxide-BN-based sintered compact for a sputtering target according to any one of [1] to [6] above, comprising: mixing an Fe—Pt-based alloy powder with an oxide powder to form an oxide-alloy composite powder in which the oxide is finely dispersed within an Fe—Pt-based alloy; then adding a BN powder to the oxide-alloy composite powder to form a BN-containing oxide-alloy composite powder; and subsequently sintering the BN-containing oxide-alloy composite powder at a temperature of 850° C. or lower.

[9] A method of producing the Fe—Pt-oxide-BN-based sintered compact for a sputtering target according to any one of [1] to [6] above, comprising: strongly mixing an Fe—Pt-based alloy powder with an oxide powder to form an oxide-alloy composite powder in which the oxide is finely dispersed within an Fe—Pt-based alloy; then adding a BN powder to the oxide-alloy composite powder and weakly mixing to form a BN-containing oxide-alloy composite powder; and subsequently sintering the BN-containing oxide-alloy composite powder at a temperature of 850° C. or lower.

### Advantageous Effects of Invention

An Fe—Pt-oxide-BN-based sintered compact for a sputtering target of the present invention can provide a high-density sputtering target with a reduced number of particles generated during sputtering.

According to the present invention, it is possible to produce, by low-temperature sintering alone without requiring hot isostatic pressing, an Fe—Pt-oxide-BN-based sintered compact for a high-density sputtering target with a reduced number of particles generated during sputtering.

### Description of Embodiments

According to the present invention, an Fe—Pt-oxide-BN-based sintered compact for a sputtering target having a mass ratio of N to B (N/B) in a range of 1.30±0.1 and preferably 1.30+0.1 is provided. BN (boron nitride) as a nonmagnetic material, together with an oxide, exists between magnetic Fe—Pt alloy phases to form partitions therebetween. The present inventors investigated sputtering targets that generate a large number of particles and discovered a phenomenon that a mass ratio (N/B) of N (nitrogen) to B (boron) in Fe—Pt-oxide-BN-based sintered compacts is less than the stoichiometric ratio. In view of this, it was presumed that BN and an oxide come into contact with each other and decompose; N is released as nitrogen gas or nitrogen oxide gas due to decomposition of BN (boron nitride); and consequently, BN and the oxide are readily peeled off as particles. Accordingly, it was understood that preventing decomposition of BN is effective for suppressing generation of particles. Here, the mass ratio of N to B (N/B) of 1.30±0.1 is almost equal to the mass ratio of 1.30 when the stoichiometric ratio of N to B is 1 and indicates that decomposition of BN into B and N is suppressed without excessively lowering N through release as nitrogen gas or nitrogen oxide gas.

An Fe—Pt-oxide-BN-based sintered compact for a sputtering target of the present invention has a relative density of 92.0% or more, preferably 94.0% or more, and more preferably 95.0% or more. Since a BN-containing Fe—Pt-oxide-based sintered compact typically has a low relative density, a relative density of 92.0% or more is deemed extremely high. In the present application, the “relative density” is measured by the Archimedes method.

An Fe—Pt-oxide-BN-based sintered compact for a sputtering target of the present invention has the composition containing 33 mol % or more and 60 mol % or less of Pt and 5 mol % or more and 40 mol % or less of BN and the oxide in total, with the balance being Fe and incidental impurities; the composition containing 33 mol % or more and 60 mol % or less of Pt, 5 mol % or more and 40 mol % or less of BN and an oxide in total, and 1 mol % or more and 15 mol % or less of one or more selected from Co, Zn, Ge, Rh, Ru, and Pd, with the balance being Fe and incidental impurities; or the composition containing 33 mol % or more and 60 mol % or less of Pt, 5 mol % or more and 40 mol % or less of BN and the oxide in total, and 1 mol % or more and 15 mol % or less of C, with the balance being Fe and incidental impurities. Both BN and the oxide are included at more than 0 mol % and may be included at an appropriate ratio provided that the total is 5 mol % or more and 40 mol % or less. However, BN is preferably included at 1 mol % or more and 30 mol % or less and the oxide is preferably included at 1 mol % or more and 15 mol % or less. The oxide is Si oxide, Ti oxide, or Ta oxide, for example, preferably SiO, SiO₂, Si₃O₂, TiO, TiO₂, or Ti₂O₃, and more preferably SiO₂, TiO₂, or Ta₂O₅.

An Fe—Pt-oxide-BN-based sintered compact for a sputtering target of the present invention has the Pt content of 33 mol % or more and 60 mol % or less, preferably 33 mol % or more and 52 mol % or less, and more preferably 35 mol % or more and 47 mol % or less.

An Fe—Pt-oxide-BN-based sintered compact for a sputtering target of the present invention has the total content of BN and the oxide of 5 mol % or more and 40 mol % or less, preferably 5 mol % or more and 35 mol % or less, and more preferably 6 mol % or more and 30 mol % or less. The BN content is 1 mol % or more and 30 mol % or less, preferably 2 mol % or more and 28 mol % or less, and more preferably 3 mol % or more and 25 mol % or less. Meanwhile, the oxide content is 1 mol % or more and 15 mol % or less, preferably 2 mol % or more and 15 mol % or less, and more preferably 3 mol % or more and 15 mol % or less. Within the above-mentioned ranges, BN and the oxide satisfactorily act as grain boundary materials.

When an Fe—Pt-oxide-BN-based sintered compact for a sputtering target contains one or more selected from Co, Zn, Ge, Rh, Ru, and Pd, the content of these metals is 1 mol % or more and 15 mol % or less, preferably 1 mol % or more and 13 mol % or less, and more preferably 1 mol % or more and 10 mol % or less. Within the above-mentioned ranges, it is possible to satisfactorily maintain the magnetic characteristics of an Fe—Pt alloy.

When an Fe—Pt-oxide-BN-based sintered compact for a sputtering target contains C, the C content is 1 mol % or more and 15 mol % or less, preferably 1 mol % or more and 13 mol % or less, and more preferably 1 mol % or more and 10 mol % or less. Within the above-mentioned ranges, C can satisfactorily act as a grain boundary material together with BN and the oxide and isolate Fe—Pt alloy grains, thereby satisfactorily maintaining the magnetic characteristics of an Fe—Pt alloy.

An Fe—Pt-oxide-BN-based sintered compact for a sputtering target of the present invention can be produced by: mixing a metal powder, an oxide powder, and a BN powder; and sintering at a low temperature of 850° C. or lower, preferably 830° C. or lower, more preferably 800° C. or lower and 730° C. or higher, and preferably 750° C. or higher. The metal powder, oxide powder, and BN powder are preferably mixed by weak mixing at 300 rpm for about 30 minutes, for example. By employing mild mixing conditions, it is possible to prevent excessive contact between BN and the oxide. Moreover, by lowering a sintering temperature, it is possible to suppress reactions between BN and the oxide and to prevent decomposition of BN. Meanwhile, since an excessively short mixing time results in poor dispersibility, the mixing time is preferably 15 minutes or more and 45 minutes or less. Here, the term “metal powder” indicates, in addition to Fe metal powder and Pt metal powder, each metal powder of one or more selected from Co, Zn, Ge, Rh, Ru, and Pd, which may be used as components of an Fe—Pt-oxide-BN-based sintered compact for a sputtering target of the present invention, or alloy powder thereof.

Alternatively, an Fe—Pt-oxide-BN-based sintered compact for a sputtering target of the present invention can be produced by: mixing an Fe—Pt-based alloy powder with an oxide powder to form an oxide-alloy composite powder in which the oxide is finely dispersed within an Fe—Pt-based alloy; then adding a BN powder to the oxide-alloy composite powder to form a BN-containing oxide-alloy composite powder; and subsequently sintering the BN-containing oxide-alloy composite powder at a low temperature of 850° C. or lower, preferably 830° C. or lower, more preferably 800° C. or lower and 730° C. or higher, and preferably 750° C. or higher.

The BN-containing oxide-alloy composite powder as a sintering precursor is formed by: mixing an Fe—Pt-based alloy powder with an oxide powder to yield an oxide-alloy composite powder in which the oxide is finely dispersed within an Fe—Pt-based alloy; and mixing a BN powder with the composite powder. By first forming the oxide-alloy composite powder in which the oxide is finely dispersed within an Fe—Pt-based alloy, it is possible to finely and uniformly disperse the Fe—Pt-based alloy and the oxide, thereby preventing excessive contact between the oxide and the BN powder to be added later.

It is preferable to prepare the oxide-alloy composite powder by strong mixing and to prepare the BN-containing oxide-alloy composite powder by weak mixing. In the present application, the term “strong mixing” indicates mixing that is performed at 300 rpm or more for 1 hour or more while providing large mixing energy, whereas the term “weak mixing” indicates mixing that is performed at 300 rpm or less for less than 1 hour while providing small mixing energy. The rotation number and mixing time for strong mixing and weak mixing may be appropriately adjusted within the above-mentioned ranges depending on the composition of the oxide-alloy composite powder and the BN-containing oxide-alloy composite powder as well as desirable dispersion states of the oxide. To obtain an oxide-alloy composite powder in which the oxide is further uniformly dispersed, for example, strong mixing at 300 rpm or more for 20 hours or more is preferable. The mixing energy increases as the rotation number is increased and the mixing time is extended. For example, at 400 rpm, mixing may be performed for 10 hours or more. Meanwhile, to further suppress reactions between BN and the oxide, the oxide-alloy composite powder and the BN powder are preferably mixed by weak mixing at 300 rpm or less for 30 minutes or less.

Although depending on a desirable composition of a sintered compact, the sintering temperature of the BN-containing oxide-alloy composite powder is considerably lower than the conventionally common sintering temperature of 900° C. or higher and 1,400° C. or lower. By sintering at a low temperature of 850° C. or lower, preferably 830° C. or lower, more preferably 800° C. or lower and 730° C. or higher, and preferably 750° C. or higher, it is possible to suppress decomposition of BN due to contact between BN and an oxide and to increase the density of a sintered compact.

When an Fe—Pt-oxide-BN-based sintered compact for a sputtering target of the present invention contains, as additional components, one or more selected from Co, Zn, Ge, Rh, Ru, and Pd, these metals as element powder or alloy powder, together with Fe metal powder and Pt metal powder, may be mixed with oxide powder and BN powder. Alternatively, the element powder or alloy powder, together with Fe—Pt alloy powder, may be mixed with oxide powder and then with BN powder.

### EXAMPLES

Hereinafter, the present invention will be specifically described by means of the Examples. However, the present invention is not limited to these Examples.

The measuring methods for the N concentration and B concentration in each Example and Comparative Example are as follows.

[N Concentration Measurement]

The N (nitrogen) concentration is measured by using an oxygen/nitrogen determinator (TC-600 from LECO Japan Corporation, thermal conductivity method).

| | |
|---|---|
| Output: | 5,200 W (2,842° C.) |
| Flux: | Ni capsules graphite powder |
| | 0.06 g Sn pellets 0.5 g |
| Mass of measuremen sample: | 0.1 g |
| Calibration sample: | Si₃N₄ |

[B Concentration Measurement]

A sample is ground in a vibration mill, and about 0.1 g of the sample is weighed out and placed in a Zr crucible for alkali fusion. About 0.5 g of sodium carbonate is added to the sample as a fusing agent, the sample and sodium carbonate are ground sufficiently with a stirring rod, and subsequently, about 2.0 g of sodium peroxide is added to the Zr crucible. The Zr crucible is then subjected to heat melting (900° C.) in a high-frequency alkali fusion apparatus, followed by spontaneous cooling. The Zr crucible after cooling is placed in a beaker, immersed in water by adding about 50 mL of pure water, and acidified by adding about 20 mL of concentrated hydrochloric acid. The beaker is then placed on a hot plate and heated for about 1 hour until the sample is completely dissolved to terminate reactions, followed by spontaneous cooling. The solution after cooling is transferred to a 100 mL volumetric flask, and a sample solution of 1,000 ppm (100 mg/100 mL) concentration is prepared. The sample solution is then transferred to a plastic bottle and diluted 25-fold to prepare a measurement solution. The prepared measurement solution is analyzed by ICP (SPECTRO ARCOS ICP-OES analyzer), and the B (boron) concentration (wt %) is calculated from the analyzed result.

[Relative Density]

The relative density is measured by the Archimedes method using pure water as an replacement liquid. First, an actual density (g/cm³) is determined by: measuring the mass of a test piece; measuring a buoyant force (=the volume of the test piece) when the test piece floating on the replacement liquid is fully submerged; and dividing the mass (g) of the test piece by the volume (cm³) of the test piece. The ratio of the actual density to a theoretical density calculated on the basis of the composition of a sintered compact (actual density/theoretical density) is a relative density.

[The Number of Particles]

A sintered compact for a target (diameter of 153 mm, thickness of 2 mm) bonded to a Cu backing plate (diameter of 161 mm, thickness of 4 mm) was fixed to a magnetron sputtering apparatus. After sputtering at an output of 500 W and a gas pressure of 1 Pa for 2 seconds, the number of particles adhered onto a substrate was determined by a particle counter.

### Example 1

To achieve Fe-35Pt-25BN-5SiO₂, 640.00 g of Fe-50Pt atomized powder (average particle size of 50 μm), 21.89 g of SiO₂ powder (average particle size of less than 1 μm), and 45.22 g of BN powder (average particle size of 15 μm) were weighed. First, Fe-50Pt atomized powder (average particle size of 50 μm) and SiO₂ powder (average particle size of less than 1 μm) were mixed in a ball mill at 450 rpm for 60 hours (vigorous mixing) to form oxide-alloy composite powder. Then, BN powder (average particle size of 15 μm) was added to the oxide-alloy composite powder and further mixed at 300 rpm for 5 minutes (weak mixing) to prepare BN-containing oxide-alloy composite powder.

The BN-containing oxide-alloy composite powder was sintered under vacuum at a sintering temperature of 830° C. and a sintering pressure of 65.60 MPa to yield an Fe—Pt—SiO₂—BN-based sintered compact for a sputtering target. The sintered compact had a relative density measured by the Archimedes method of 98.3%, N/B of 1.25, which is within the theoretical value range of 1.30±0.1, and the number of particles of 42, which is small. Presumably, decomposition of BN was suppressed, thereby suppressing generation of particles.

Here, the average particle size of the raw material powder is a D₅₀ value (the same applies to the following Examples and Comparative Examples).

### Examples 2 to 6

Each Fe—Pt-oxide-BN-based sintered compact for a sputtering target was obtained in the same manner as Example 1 except for changing the composition and sintering temperature as shown in Table 1. The measured results of the relative density, N/B, and the number of particles are shown in Table 1. The relative density is 96% or more, N/B is 1.29 to 1.38, which is within the theoretical value range of 1.30±0.1, and the number of particles is 28 or less, which is small. Presumably, decomposition of BN was suppressed, thereby suppressing generation of particles.

### Example 7

To achieve Fe-40Pt-10BN-10SiO₂, 146.12 g of Fe powder (average particle size of 6 μm), 510.41 g of Pt powder (average particle size of 1 μm), 39.30 g of SiO₂ powder (average particle size of less than 1 μm), and 16.23 g of BN powder (average particle size of 15 μm) were weighed and mixed in a ball mill at 300 rpm for 30 minutes.

The resulting mixture was sintered under vacuum at a sintering temperature of 780° C. and a sintering pressure of 65.60 MPa to yield an Fe—Pt—SiO₂—BN-based sintered compact for a sputtering target. The sintered compact had a relative density measured by the Archimedes method of 97.0%, N/B of 1.28, which is within the theoretical value range of 1.30±0.1, and the number of particles of 35, which is small. Presumably, decomposition of BN was suppressed, thereby suppressing generation of particles.

### Examples 8 and 9

Each Fe—Pt-oxide-BN-based sintered compact for a sputtering target was obtained in the same manner as Example 7 except for using TiO₂ (average particle size of 2 μm, Example 8) or Ta₂O₅ (average particle size of 3 μm, Example 9) as an oxide as well as changing the composition as shown in Table 1. The measured results of the relative density, N/B, and the number of particles are shown in Table 1. The relative density is 92% or more, N/B is 1.22 to 1.24, which is within the theoretical value range of 1.30±0.1, and the number of particles is 55 or less, which is small. Presumably, decomposition of BN was suppressed, thereby suppressing generation of particles.

### Example 10

To achieve Fe-35Pt-10Co-10BN-10SiO_{2, 136.16} g of Fe powder (average particle size of 6 μm), 475.64 g of Pt powder (average particle size of 1 μm), 41.05 g of Co powder (average particle size of 5 μm), 41.86 g of SiO₂ powder (average particle size of less than 1 μm), and 17.29 g of BN powder (average particle size of 15 μm) were weighed and mixed in a ball mill at 300 rpm for 30 minutes.

The resulting mixture was sintered under vacuum at a sintering temperature of 780° C. and a sintering pressure of 65.60 MPa to yield an Fe—Pt—SiO₂-BN-based sintered compact for a sputtering target. The sintered compact had a relative density measured by the Archimedes method of 95.6%, N/B of 1.40, which is within the theoretical value range of 1.30±0.1, and the number of particles of 15, which is small. Presumably, decomposition of BN was suppressed, thereby suppressing generation of particles.

### Examples 11 to 15

Each Fe—Pt-oxide-BN-based sintered compact for a sputtering target was obtained in the same manner as Example 10 except for using, as an additional metal component, Zn powder (average particle size of 7 μm, Example 11), Ge powder (average particle size of 20 μm, Example 12), Rh powder (average particle size of 20 μm, Example 13), Ru powder (average particle size of 6 μm, Example 14), or Pd powder (average particle size of 3 μm, Example 15) as well as changing the composition and sintering temperature as shown in Table 1. The measured results of the relative density, N/B, and the number of particles are shown in Table 1. The relative density is 92% or more, N/B is 1.20 to 1.35, which is within the theoretical value range of 1.30±0.1, and the number of particles is 40 or less, which is small. Presumably, decomposition of BN was suppressed, thereby suppressing generation of particles.

### Example 16

To achieve Fe-35Pt-10BN-10SiO₂-10C, 144.32 g of Fe powder (average particle size of 6 μm), 504.13 g of Pt powder (average particle size of 1 μm), 44.36 g of SiO₂ powder (average particle size of less than 1 μm), 18.33 g of BN powder (average particle size of 15 μm), and 8.87 g of C (average particle size of 10 μm) were weighed and mixed in a ball mill at 300 rpm for 30 minutes.

The resulting mixture was sintered under vacuum at a sintering temperature of 780° C. and a sintering pressure of 65.60 MPa to yield an Fe—Pt-SiO₂-BN-based sintered compact for a sputtering target. The sintered compact had a relative density measured by the Archimedes method of 92.6%, N/B of 1.26, which is within the theoretical value range of 1.30±0.1, and the number of particles of 45, which is small. Presumably, decomposition of BN was suppressed, thereby suppressing generation of particles.

### Comparative Example 1

An Fe—Pt-oxide-BN-based sintered compact for a sputtering target was obtained in the same manner as Example 1 except for changing the sintering temperature to 950° C. The measured results of the relative density, N/B, and the number of particles are shown in Table 1. The relative density is as low as 87.6% or less, N/B is 1.12 and smaller than the theoretical value of 1.30 by more than 0.1, and the number of particles is 220, which is large. Presumably, BN decomposed, thereby generating nitrogen gas or nitrogen oxide gas.

### Comparative Example 2

An Fe—Pt-oxide-BN-based sintered compact for a sputtering target was obtained in the same manner as Example 3 except for changing the sintering temperature to 950° C. The measured results of the relative density, N/B, and the number of particles are shown in Table 1. The relative density is as low as 83.8% or less, N/B is 1.13 and smaller than the theoretical value of 1.30 by more than 0.1, and the number of particles is 189, which is large. Presumably, BN decomposed, thereby generating nitrogen gas or nitrogen oxide gas.

### Comparative Example 3

An Fe—Pt-oxide-BN-based sintered compact for a sputtering target was obtained in the same manner as Example 5 except for changing the sintering temperature to 950° C. The measured results of the relative density, N/B, and the number of particles are shown in Table 1. The relative density is as low as 88.1% or less, N/B is 1.05 and smaller than the theoretical value of 1.30 by more than 0.1, and the number of particles is 128, which is large. Presumably, BN decomposed, thereby generating nitrogen gas or nitrogen oxide gas.

### Comparative Example 4

An Fe—Pt-oxide-BN-based sintered compact for a sputtering target was obtained in the same manner as Example 7 except for changing the sintering temperature to 950° C. as well as the mixing conditions to 300 rpm for 3 hours. The obtained sintered compact had the relative density measured by the Archimedes method of as low as 89.8%, N/B of 1.10, which is smaller than the theoretical value of 1.30 by more than 0.1, and the number of particles of 135, which is large. Presumably, BN decomposed, thereby generating nitrogen gas or nitrogen oxide gas.

### Comparative Example 5

An Fe—Pt-oxide-BN-based sintered compact for a sputtering target was obtained in the same manner as Example 8 except for changing the sintering temperature to 950° C. as well as the mixing conditions to 300 rpm for 3 hours. The measured results of the relative density, N/B, and the number of particles are shown in Table 1. The relative density is as low as 90.3% or less, N/B is 1.19 and smaller than the theoretical value of 1.30 by more than 0.1, and the number of particles is 356, which is extremely large. Presumably, BN decomposed, thereby generating nitrogen gas or nitrogen oxide gas.

### Comparative Example 6

An Fe—Pt-oxide-BN-based sintered compact for a sputtering target was obtained in the same manner as Example 10 except for changing the sintering temperature to 950° C. as well as the mixing conditions to 300 rpm for 3 hours. The measured results of the relative density, N/B, and the number of particles are shown in Table 1. The relative density is as low as 88.5% or less, N/B is 1.11 and smaller than the theoretical value of 1.30 by more than 0.1, and the number of particles is 114, which is large. Presumably, BN decomposed, thereby generating nitrogen gas or nitrogen oxide gas.

TABLE 1
Composition and Physical properties of each target

| | | Sintering | | | | | |
|---|---|---|---|---|---|---|---|
| | | temperature | Density | N | B | | Particles |
| | Composition | (° C.) | (%) | (wt %) | (wt %) | N/B | (count) |
| Ex. 1 | Fe—35Pt—25BN—5SiO₂ | 830 | 98.3 | 3.55 | 2.84 | 1.25 | 42 |
| Ex. 2 | Fe—37.5Pt—18BN—7SiO₂ | 830 | 98.6 | 2.46 | 1.85 | 1.33 | 28 |
| Ex. 3 | Fe—40Pt—10BN—10SiO₂ | 780 | 98.8 | 1.33 | 0.97 | 1.37 | 12 |
| Ex. 4 | Fe—40Pt—8BN—12SiO₂ | 830 | 98.0 | 0.99 | 0.77 | 1.29 | 20 |
| Ex. 5 | Fe—40.5Pt—4BN—15SiO₂ | 830 | 98.0 | 0.51 | 0.37 | 1.38 | 13 |
| Ex. 6 | Fe—47Pt—3BN—3SiO₂ | 780 | 96.2 | 0.38 | 0.28 | 1.36 | 8 |
| Ex. 7 | Fe—40Pt—10BN—10SiO₂ | 780 | 97.0 | 1.32 | 1.03 | 1.28 | 35 |
| Ex. 8 | Fe—40Pt—10BN—10TiO₂ | 780 | 92.8 | 1.22 | 1.00 | 1.22 | 55 |
| Ex. 9 | Fe—41.5Pt—10BN—7Ta₂O₅ | 780 | 92.6 | 0.99 | 0.80 | 1.24 | 35 |
| Ex. 10 | Fe—35Pt—10Co—10BN—10SiO₂ | 780 | 95.6 | 1.40 | 1.00 | 1.40 | 15 |
| Ex. 11 | Fe—35Pt—10Zn—10BN—10SiO₂ | 780 | 94.4 | 1.32 | 1.10 | 1.20 | 11 |
| Ex. 12 | Fe—35Pt—10Ge—10BN—10SiO₂ | 730 | 92.2 | 1.31 | 1.06 | 1.24 | 22 |
| Ex. 13 | Fe—35Pt—10Rh—10BN—10SiO₂ | 780 | 95.3 | 1.33 | 1.01 | 1.32 | 31 |
| Ex. 14 | Fe—35Pt—10Ru—10BN—10SiO₂ | 780 | 92.3 | 1.35 | 1.00 | 1.35 | 40 |
| Ex. 15 | Fe—35Pt—10Pd—10BN—10SiO₂ | 780 | 96.4 | 1.36 | 1.02 | 1.33 | 15 |
| Ex. 16 | Fe—35Pt—10BN—10SiO₂—10C | 780 | 92.6 | 1.39 | 1.10 | 1.26 | 45 |
| Comp. Ex. 1 | Fe—35Pt—25BN—5SiO₂ | 950 | 87.6 | 3.10 | 2.77 | 1.12 | 220 |
| Comp. Ex. 2 | Fe—40Pt—10BN—10SiO₂ | 950 | 83.8 | 1.08 | 0.96 | 1.13 | 189 |
| Comp. Ex. 3 | Fe—40.5Pt—4BN—15SiO₂ | 950 | 88.1 | 0.39 | 0.37 | 1.05 | 128 |
| Comp. Ex. 4 | Fe—40Pt—10BN—10SiO₂ | 950 | 89.8 | 1.06 | 0.96 | 1.10 | 135 |
| Comp. Ex. 5 | Fe—40Pt—10BN—10TiO₂ | 950 | 90.3 | 1.12 | 0.94 | 1.19 | 356 |
| Comp. Ex. 6 | Fe—35Pt—10Co—10BN—10SiO₂ | 950 | 88.5 | 1.14 | 1.03 | 1.11 | 114 |

1. An Fe—Pt-oxide-BN-based sintered compact for a sputtering target, wherein a mass ratio of N to B (NB) is in a range of 1.30±0.1.

2. The Fe—Pt-oxide-BN-based sintered compact for a sputtering target according to claim 1, wherein a relative density measured by the Archimedes method is 92.0% or more.

3. The Fe—Pt-oxide-BN-based sintered compact for a sputtering target according to claim 1, comprising 33 mol % or more and 60 mol % or less of Pt and 5 mol % or more and 40 mol % or less of BN and an oxide in total, with the balance being Fe and incidental impurities.

4. The Fe—Pt-oxide-BN-based sintered compact for a sputtering target according to claim 1, comprising 33 mol % or more and 60 mol % or less of Pt, 5 mol % or more and 40 mol % or less of BN and an oxide in total, and 1 mol % or more and 15 mol % or less of one or more selected from Co, Zn, Ge, Rh, Ru, and Pd, with the balance being Fe and incidental impurities.

5. The Fe—Pt-oxide-BN-based sintered compact for a sputtering target according to claim 1 or 2, comprising 33 mol % or more and 60 mol % or less of Pt, 5 mol % or more and 40 mol % or less of BN and an oxide in total, and 1 mol % or more and 15 mol % or less of C, with the balance being Fe and incidental impurities.

6. The Fe—Pt-oxide-BN-based sintered compact for a sputtering target according to claim 1, wherein the oxide is selected from Si oxide, Ti oxide, and Ta oxide.

7. A method of producing the Fe—Pt-oxide-BN-based sintered compact for a sputtering target according to claim 1, comprising: mixing a metal powder, an oxide powder, and a BN powder; and sintering at a temperature of 850° C. or lower.

8. A method of producing the Fe—Pt-oxide-BN-based sintered compact for a sputtering target according to claim 1, comprising: mixing an Fe—Pt-based alloy powder with an oxide powder to form an oxide-alloy composite powder in which the oxide is finely dispersed within an Fe—Pt-based alloy; then adding a BN powder to the oxide-alloy composite powder to form a BN-containing oxide-alloy composite powder; and subsequently sintering the BN-containing oxide-alloy composite powder at a temperature of 850° C. or lower.

9. A method of producing the Fe—Pt-oxide-BN-based sintered compact for a sputtering target according to claim 1, comprising: strongly mixing an Fe—Pt-based alloy powder with an oxide powder to form an oxide-alloy composite powder in which the oxide is finely dispersed within an Fe—Pt-based alloy; then adding a BN powder to the oxide-alloy composite powder and weakly mixing to form a BN-containing oxide-alloy composite powder; and subsequently sintering the BN-containing oxide-alloy composite powder at a temperature of 850° C. or lower.

10. The Fe—Pt-oxide-BN-based sintered compact for a sputtering target according to claim 1, comprising 33 mol % or more and 60 mol % or less of Pt and 5 mol % or more and 40 mol % or less of BN and an oxide in total, with the balance being Fe and incidental impurities, and wherein the oxide is selected from Si oxide, Ti oxide, and Ta oxide.

11. The Fe—Pt-oxide-BN-based sintered compact for a sputtering target according to claim 1, comprising 33 mol % or more and 60 mol % or less of Pt, 5 mol % or more and 40 mol % or less of BN and an oxide in total, and 1 mol % or more and 15 mol % or less of one or more selected from Co, Zn, Ge, Rh, Ru, and Pd, with the balance being Fe and incidental impurities, and wherein the oxide is selected from Si oxide, Ti oxide, and Ta oxide.

12. The Fe—Pt-oxide-BN-based sintered compact for a sputtering target according to claim 1, comprising 33 mol % or more and 60 mol % or less of Pt, 5 mol % or more and 40 mol % or less of BN and an oxide in total, and 1 mol % or more and 15 mol % or less of C, with the balance being Fe and incidental impurities and wherein the oxide is selected from Si oxide, Ti oxide, and Ta oxide.

13. A method of producing the Fe—Pt-oxide-BN-based sintered compact for a sputtering target according to claim 1 that comprises 33 mol % or more and 60 mol % or less of Pt and 5 mol % or more and 40 mol % or less of BN and an oxide in total, with the balance being Fe and incidental impurities, wherein the method comprising:
mixing a metal powder, an oxide powder, and a BN powder; and
sintering at a temperature of 850° C. or lower.

14. A method of producing the Fe—Pt-oxide-BN-based sintered compact for a sputtering target according to claim 1 that comprises 33 mol % or more and 60 mol % or less of Pt and 5 mol % or more and 40 mol % or less of BN and an oxide in total, with the balance being Fe and incidental impurities, wherein the method comprising:
mixing an Fe—Pt-based alloy powder with an oxide powder to form an oxide-alloy composite powder in which the oxide is finely dispersed within an Fe—Pt-based alloy;
then adding a BN powder to the oxide-alloy composite powder to form a BN-containing oxide-alloy composite powder; and
subsequently sintering the BN-containing oxide-alloy composite powder at a temperature of 850° C. or lower.

15. A method of producing the Fe—Pt-oxide-BN-based sintered compact for a sputtering target according to claim 1 that comprises 33 mol % or more and 60 mol % or less of Pt and 5 mol % or more and 40 mol % or less of BN and an oxide in total, with the balance being Fe and incidental impurities, wherein the method comprising:
strongly mixing an Fe—Pt-based alloy powder with an oxide powder to form an oxide-alloy composite powder in which the oxide is finely dispersed within an Fe—Pt-based alloy;
then adding a BN powder to the oxide-alloy composite powder and weakly mixing to form a BN-containing oxide-alloy composite powder; and
subsequently sintering the BN-containing oxide-alloy composite powder at a temperature of 850° C. or lower.

16. A method of producing the Fe—Pt-oxide-BN-based sintered compact for a sputtering target according to claim 1 that comprises 33 mol % or more and 60 mol % or less of Pt, 5 mol % or more and 40 mol % or less of BN and an oxide in total, and 1 mol % or more and 15 mol % or less of one or more selected from Co, Zn, Ge, Rh, Ru, and Pd, with the balance being Fe and incidental impurities, wherein the method comprising:
mixing a metal powder, an oxide powder, and a BN powder; and
sintering at a temperature of 850° C. or lower.

17. A method of producing the Fe—Pt-oxide-BN-based sintered compact for a sputtering target according to claim 1 that comprises 33 mol % or more and 60 mol % or less of Pt, 5 mol % or more and 40 mol % or less of BN and an oxide in total, and 1 mol % or more and 15 mol % or less of one or more selected from Co, Zn, Ge, Rh, Ru, and Pd, with the balance being Fe and incidental impurities, wherein the method comprising:
mixing an Fe—Pt-based alloy powder with an oxide powder to form an oxide-alloy composite powder in which the oxide is finely dispersed within an Fe—Pt-based alloy; then adding a BN powder to the oxide-alloy composite powder to form a BN-containing oxide-alloy composite powder; and
subsequently sintering the BN-containing oxide-alloy composite powder at a temperature of 850° C. or lower.

18. A method of producing the Fe—Pt-oxide-BN-based sintered compact for a sputtering target according to claim 1 that comprises 33 mol % or more and 60 mol % or less of Pt, 5 mol % or more and 40 mol % or less of BN and an oxide in total, and 1 mol % or more and 15 mol % or less of one or more selected from Co, Zn, Ge, Rh, Ru, and Pd, with the balance being Fe and incidental impurities and wherein the method comprising:
strongly mixing an Fe—Pt-based alloy powder with an oxide powder to form an oxide-alloy composite powder in which the oxide is finely dispersed within an Fe—Pt-based alloy;
then adding a BN powder to the oxide-alloy composite powder and weakly mixing to form a BN-containing oxide-alloy composite powder; and
subsequently sintering the BN-containing oxide-alloy composite powder at a temperature of 850° C. or lower.

19. A method of producing the Fe—Pt-oxide-BN-based sintered compact for a sputtering target according to claim 1 that comprises 33 mol % or more and 60 mol % or less of Pt, 5 mol % or more and 40 mol % or less of BN and an oxide in total, and 1 mol % or more and 15 mol % or less of C, with the balance being Fe and incidental impurities, wherein the method comprising:
mixing a metal powder, an oxide powder, and a BN powder; and
sintering at a temperature of 850° C. or lower.

20. A method of producing the Fe—Pt-oxide-BN-based sintered compact for a sputtering target according to claim 1 that comprises 33 mol % or more and 60 mol % or less of Pt, 5 mol % or more and 40 mol % or less of BN and an oxide in total, and 1 mol % or more and 15 mol % or less of C, with the balance being Fe and incidental impurities, wherein the method comprising:
mixing an Fe—Pt-based alloy powder with an oxide powder to form an oxide-alloy composite powder in which the oxide is finely dispersed within an Fe—Pt-based alloy;
then adding a BN powder to the oxide-alloy composite powder to form a BN-containing oxide-alloy composite powder; and
subsequently sintering the BN-containing oxide-alloy composite powder at a temperature of 850° C. or lower.

21. A method of producing the Fe—Pt-oxide-BN-based sintered compact for a sputtering target according to claim 1 that comprises 33 mol % or more and 60 mol % or less of Pt, 5 mol % or more and 40 mol % or less of BN and an oxide in total, and 1 mol % or more and 15 mol % or less of C, with the balance being Fe and incidental impurities, wherein the method comprising:
strongly mixing an Fe—Pt-based alloy powder with an oxide powder to form an oxide-alloy composite powder in which the oxide is finely dispersed within an Fe—Pt-based alloy;
then adding a BN powder to the oxide-alloy composite powder and weakly mixing to form a BN-containing oxide-alloy composite powder; and
subsequently sintering the BN-containing oxide-alloy composite powder at a temperature of 850° C. or lower.
